(19) United States
(12) Patent Application Publication
(10) Pub. No.: US 2025/0253237 A1
(43) Pub. Date: Aug. 7, 2025

(54) DISPLAY PANEL AND DISPLAY DEVICE

(71) Applicant: Yungu (Gu’an) Technology Co., Ltd., Langfang (CN)

(72) Inventors: Xin ZHAO, Langfang (CN); Guangyuan SUN, Langfang (CN); Zhili MA, Langfang (CN); Linhua GAO, Langfang (CN); Pei DUAN, Langfang (CN); Yongqiang LI, Langfang (CN); Xiaosheng YAN, Langfang (CN)

(73) Assignee: Yungu (Gu’an) Technology Co., Ltd., Langfang (CN)

(21) Appl. No.: 19/187,944

(22) Filed: Apr. 23, 2025

(30) Foreign Application Priority Data
Apr. 30, 2024 (CN) 202410546060.7

(51) Int. Cl. H01L 23/528; H10H 29/49; H10K 59/82

(52) U.S. Cl. CPC H01L 23/528; H10H 29/49; H10K 59/82

(57) ABSTRACT

Disclosed are a display panel and a display device. The display panel includes an active area and a non-active area arranged in a first direction; where the active area includes a plurality of first signal lines extending in the first direction and arranged in a second direction, the first direction intersecting the second direction; the non-active area also includes a plurality of fan-out lines electrically connected to the plurality of first signal lines, respectively; a bending area is provided with a plurality of avoidance areas, and the fan-out lines avoid the avoidance areas; in two fan-out lines adjacent to the avoidance area in the second direction and on different sides of the avoidance area, a section of one fan-out line in a first fan-out area includes a first extension segment and a second extension segment connected to the first extension segment.

The present application claims priority to Chinese patent application no. 202410546060.7, filed with the China National Intellectual Property Administration on Apr. 30, 2024 and entitled “DISPLAY PANEL AND DISPLAY DEVICE”, which is incorporated herein by reference in its entirety.

### FIELD

The present disclosure relates to the field of display, and in particular to a display panel and a display device.

### BACKGROUND ART

With the development of display technologies, the application of display panels is becoming more and more extensive, and correspondingly, requirements for display panels are increasingly high.

However, an overloaded split-screen phenomenon, i.e., vertical stripes, is likely to occur to a display panel in the related art during display, which limits the further development of the display panel.

### SUMMARY

The present disclosure provides a display panel and a display device, in order to relieve the phenomenon of vertical stripes during display and enhance the display effect.

According to one embodiment of the present disclosure, provided is a display panel including an active area and a non-active area arranged in a first direction, where the non-active area includes a first fan-out area, a bending area and a second fan-out area, which are sequentially away from the active area; the active area includes a plurality of first signal lines extending in the first direction and arranged in a second direction, the first direction intersecting the second direction;

the non-active area also includes a plurality of fan-out lines electrically connected to the plurality of first signal lines, respectively; the bending area is provided with a plurality of avoidance areas, and the fan-out lines avoid, which means not entering, being separated from, the avoidance areas; and

in two fan-out lines adjacent to the avoidance area in the second direction and on different sides of the avoidance area, a section of one fan-out line in the first fan-out area includes a first extension segment and a second extension segment connected to the first extension segment; a section of the other fan-out line in the second fan-out area includes a first extension segment and a second extension segment connected to the first extension segment; the first extension segments are configured to bypass a corresponding avoidance area in the second direction; and the first extension segments of the two adjacent fan-out lines on different sides of the avoidance area have the same line width.

In one embodiment, in the same fan-out line, an included angle between the first extension segment and the second direction is smaller than an included angle between the corresponding second extension segment and the second direction; or the first extension segment is collinear with the second extension segment, and in the first direction, an orthographic projection of the first extension segment overlaps a projection of a corresponding avoidance area, and an orthographic projection of the second extension segment does not overlap a projection of the corresponding avoidance area;

In one embodiment, in the two fan-out lines adjacent to the avoidance area in the second direction and on different sides of the avoidance area, a section of the first fan-out line located in the first fan-out area includes a first extension segment and a second extension segment, and a section of the second fan-out line located in the second fan-out area includes a first extension segment and a second extension segment; where the first fan-out line is the fan-out line close to a centerline of the bending area, and the second fan-out line is the fan-out line away from the centerline of the bending area; and

In one embodiment, the section of the first fan-out line located in the second fan-out area includes a third extension segment, and the section of the second fan-out line located in the first fan-out area includes a third extension segment.

In one embodiment, the first extension segment of the first fan-out line is collinear with the corresponding second extension segment, and an included angle between the first extension segment of the second fan-out line and the second direction is smaller than an included angle between the corresponding second extension segment and the second direction;

In one embodiment, the third extension segment of the first fan-out line extends parallel to the second extension segment of the second fan-out line; and

In one embodiment, a length difference between the third extension segment of the first fan-out line and the second extension segment of the second fan-out line is less than or equal to a first preset value.

In one embodiment, the plurality of fan-out lines include a plurality of first progressive fan-out lines disposed sequentially on the side of the second fan-out line away from the centerline of the bending area; each of the first progressive fan-out lines includes a first extension segment and a second extension segment located in the second fan-out area; in a plurality of first extension segments of the plurality of first progressive fan-out lines corresponding to the second fan-out line, the widths of different first extension segments gradually increase in a direction away from the centerline of the bending area;

In one embodiment, the line width of all sections of the fan-out lines located in the second fan-out area, except for all the first extension segments, is a first line width;

In one embodiment, the line width of the first extension segment of the second fan-out line is smaller than the first line width;

In one embodiment, the maximum line width of the first extension segments of all the first progressive fan-out lines is equal to the first line width; and

In one embodiment, the difference between the line widths of corresponding first extension segments of any two adjacent first progressive fan-out lines is equal.

In one embodiment, an included angle between the first extension segment of the first fan-out line and the second direction is less than an included angle between the corresponding second extension segment and the second direction, the first extension segment of the second fan-out line being collinear with the corresponding second extension segment;

In one embodiment, the second extension segment of the first fan-out line extends parallel to the third extension segment of the second fan-out line;

In one embodiment, the length difference between the second extension segment of the first fan-out line and the third extension segment of the second fan-out line is less than or equal to a second preset value.

In one embodiment, the plurality of fan-out lines include a plurality of second progressive fan-out lines disposed sequentially on the side of the first fan-out line close to the centerline of the bending area. each of the second progressive fan-out lines includes a first extension segment and a second extension segment located in the first fan-out area; in the first extension segments of the first fan-out line corresponding to the plurality of second progressive fan-out lines, the widths of different first extension segments gradually decrease in a direction close to the centerline of the bending area;

In one embodiment, the line width of all sections of the fan-out lines located in the first fan-out area, except for all the first extension segments, is the second line width;

In one embodiment, the line width of the first extension segment of the first fan-out line is greater than the second line width;

In one embodiment, the minimum line width of the first extension segments of all the second progressive fan-out lines is equal to the second line width; and

In one embodiment, the difference between the line widths of corresponding first extension segments of any two adjacent second progressive fan-out lines is equal.

In one embodiment, an included angle between the first extension segment of the first fan-out line and the second direction is less than an included angle between the corresponding second extension segment and the second direction, and an included angle between the first extension segment of the second fan-out line and the second direction is smaller than an included angle between the corresponding second extension segment and the second direction;

In one embodiment, the second extension segment of the first fan-out line extends parallel to the third extension segment of the second fan-out line;

In one embodiment, a length difference between the second extension segment of the first fan-out line and the third extension segment of the second fan-out line is less than or equal to a third preset value;

In one embodiment, the third extension segment of the first fan-out line extends parallel to the second extension segment of the second fan-out line; and

In one embodiment, the length difference between the third extension segment of the first fan-out line and the second extension segment of the second fan-out line is less than or equal to a fourth preset value.

In one embodiment, the plurality of fan-out lines include a plurality of first progressive fan-out lines disposed sequentially on the side of the second fan-out line away from the centerline of the bending area; each of the first progressive fan-out lines includes a first extension segment and a second extension segment located in the second fan-out area; in a plurality of first extension segments of the plurality of first progressive fan-out lines corresponding to the second fan-out line, the widths of different first extension segments gradually increase in a direction away from the centerline of the bending area;

In one embodiment, the line width of all sections of the fan-out lines located in the second fan-out area, except for all the first extension segments, is a first line width; the line width of a section of the fan-out line located in the first fan-out area is the second line width;

In one embodiment, the line width of the first extension segment of the second fan-out line is smaller than the first line width;

In one embodiment, the maximum line width of the first extension segments of all the first progressive fan-out lines is equal to the first line width;

In one embodiment, the difference between the line widths of corresponding first extension segments of any two adjacent first progressive fan-out lines is equal;

In one embodiment, the plurality of fan-out lines include a plurality of second progressive fan-out lines disposed sequentially on the side of the first fan-out line close to the centerline of the bending area; each of the second progressive fan-out lines includes a first extension segment and a second extension segment located in the first fan-out area; in the first extension segments of the first fan-out line corresponding to the plurality of second progressive fan-out lines, the widths of different first extension segments gradually decrease in a direction close to the centerline of the bending area;

In one embodiment, the line width of all sections of the fan-out lines located in the first fan-out area, except for all the first extension segments, is the second line width; the line width of a section of the fan-out line located in the second fan-out area is the first line width;

In one embodiment, the line width of the first extension segment of the first fan-out line is greater than the second line width;

In one embodiment, the minimum line width of the first extension segments of all the second progressive fan-out lines is equal to the second line width; and

In one embodiment, the difference between the line widths of corresponding first extension segments of any two adjacent second progressive fan-out lines is equal.

In one embodiment, the first extension segment of the first fan-out line extends parallel to the first extension segment of the second fan-out line.

In one embodiment, the bending area further includes a plurality of hub areas, the hub areas and the avoidance areas being arranged in the second direction;

In one embodiment, a section of the fan-out line located in the bending area is disposed in the hub area;

In one embodiment, a plurality of second signal lines are also arranged within the active area, and a plurality of direct-current signal lines are arranged in the avoidance area, the direct-current signal lines being electrically connected to the second signal lines.

In one embodiment, the active area further includes a plurality of pixel drive circuits arranged in an array in the first direction and the second direction; the first signal lines are configured to provide a data signal to the pixel drive circuits;

In one embodiment, the pixel drive circuits in the same line in the first direction are electrically connected to the same first signal line.

According to another embodiment of the present disclosure, provided is a display panel including an active area and a non-active area arranged in a first direction, where the non-active area includes a bending area; the active area includes a plurality of first signal lines extending in the first direction and arranged in a second direction, the first direction intersecting the second direction;

the non-active area also includes a plurality of fan-out lines electrically connected to the plurality of first signal lines, respectively; the bending area is provided with a plurality of avoidance areas, and the fan-out lines avoid the avoidance areas; and

the two fan-out lines, which are adjacent to the avoidance area in the second direction and on different sides of the avoidance area, are equal in length and both include a first line width segment and a second line width segment, the first line width segments of the two fan-out lines have the same line width and length, and the second line width segments of the two fan-out lines have the same line width and length.

In one embodiment, the non-active area includes a first fan-out area, a bending area, and a second fan-out area, which are sequentially away from the active area;

in the same fan-out line, an included angle between the first extension segment and the second direction is smaller than an included angle between a corresponding second extension segment and the second direction; or the first extension segment is collinear with the second extension segment, and in the first direction, an orthographic projection of the first extension segment overlaps a projection of a corresponding avoidance area, and an orthographic projection of the second extension segment does not overlap a projection of the corresponding avoidance area;

In one embodiment, in the two fan-out lines adjacent to the avoidance area in the second direction and on different sides of the avoidance area, a section of the first fan-out line located in the first fan-out area includes a first extension segment and a second extension segment, and a section of the second fan-out line located in the second fan-out area includes a first extension segment and a second extension segment; where the first fan-out line is the fan-out line close to a centerline of the bending area, and the second fan-out line is the fan-out line away from the centerline of the bending area; and

In one embodiment, the section of the first fan-out line located in the second fan-out area includes a third extension segment, and the section of the second fan-out line located in the first fan-out area includes a third extension segment.

In one embodiment, the second line width segment of the first fan-out line includes the corresponding first extension segment and the corresponding second extension segment; the first line width segment of the first fan-out line includes a corresponding third extension segment; the second line width segment of the second fan-out line includes a corresponding third extension segment and a corresponding first extension segment; and the first line width segment of the second fan-out line includes a corresponding second extension segment.

In one embodiment, the width of the first line width segment in the fan-out line is greater than the width of the corresponding second line width segment.

In one embodiment, the plurality of fan-out lines include a plurality of first progressive fan-out lines disposed sequentially on the side of the second fan-out line away from the centerline of the bending area; each of the first progressive fan-out lines includes a first extension segment and a second extension segment located in the second fan-out area; in a plurality of first extension segments of the plurality of first progressive fan-out lines corresponding to the second fan-out line, the widths of different first extension segments gradually increase in a direction away from the centerline of the bending area;

In one embodiment, the line width of all sections of the fan-out lines located in the second fan-out area, except for all the first extension segments, is a first line width;

In one embodiment, the line width of the first extension segment of the second fan-out line is smaller than the first line width;

In one embodiment, the maximum line width of the first extension segments of all the first progressive fan-out lines is equal to the first line width; and

In one embodiment, the difference between the line widths of corresponding first extension segments of any two adjacent first progressive fan-out lines is equal, and preferably the lengths of the two adjacent fan-out lines are equal.

In one embodiment, the first line width segment of the first fan-out line includes the corresponding first extension segment and the corresponding second extension segment; the second line width segment of the first fan-out line includes a corresponding third extension segment; the second line width segment of the second fan-out line includes a corresponding second extension segment and a corresponding first extension segment; and the first line width segment of the second fan-out line includes a corresponding third extension segment.

In one embodiment, the width of the first line width segment in the fan-out line is greater than the width of the corresponding second line width segment.

In one embodiment, the plurality of fan-out lines include a plurality of second progressive fan-out lines disposed sequentially on the side of the first fan-out line close to the centerline of the bending area; each of the second progressive fan-out lines includes a first extension segment and a second extension segment located in the first fan-out area; in the first extension segments of the first fan-out line corresponding to the plurality of second progressive fan-out lines, the widths of different first extension segments gradually decrease in a direction close to the centerline of the bending area;

In one embodiment, the line width of all sections of the fan-out lines located in the first fan-out area, except for all the first extension segments, is the second line width;

In one embodiment, the line width of the first extension segment of the first fan-out line is greater than the second line width;

In one embodiment, the minimum line width of the first extension segments of all the second progressive fan-out lines is equal to the second line width;

In one embodiment, the difference between the line widths of corresponding first extension segments of any two adjacent second progressive fan-out lines is equal; and

In one embodiment, two adjacent fan-out lines are equal in length.

According to another embodiment of the present disclosure, a display device is provided, including the display panel as described above.

According to the embodiments of the present disclosure, a display panel is employed that includes an active area and a non-active area arranged in a first direction, where the non-active area includes a first fan-out area, a bending area, and a second fan-out area that are sequentially away from the active area; the active area includes a plurality of first signal lines extending in the first direction and arranged in a second direction, the first direction intersecting the second direction; the non-active area also includes a plurality of fan-out lines electrically connected to the plurality of first signal lines, respectively; a bending area is provided with a plurality of avoidance areas, and the fan-out lines avoid the avoidance areas; in two fan-out lines adjacent to the avoidance area in the second direction and on different sides of the avoidance area, a section of one fan-out line in a first fan-out area includes a first extension segment and a second extension segment connected to the first extension segment; a section of the other fan-out line in a second fan-out area includes a first extension segment and a second extension segment connected to the first extension segment; the first extension segments are configured to bypass a corresponding avoidance area in the second direction; and the first extension segments of the two adjacent fan-out lines on different sides of the avoidance area have the same line width. By setting the line widths of the two first extension segments to be equal such that the lengths of the sections with the same line width of the two fan-out lines on both sides of the avoidance area are similar or equal, so that the resistance difference between the two fan-out lines is small, and the difference in resistance variations caused by process variations during manufacturing is also small, which can thus greatly relieve the phenomenon of vertical stripes.

It should be understood that the content described in this section is not intended to identify key or important features of embodiments of the present disclosure, and not intended to limit the scope of the present disclosure. Other features of the present disclosure will become easy to understand through the following description.

### BRIEF DESCRIPTION OF THE DRAWINGS

In order to more clearly illustrate the embodiments of the present disclosure, the drawings required for the descriptions of the embodiments will be briefly described below. The drawings in the following description are only some embodiments of the present disclosure.

FIG. 1 is a schematic diagram of a structure of a display panel according to an embodiment of the present disclosure;

FIG. 2 is a partial enlarged view of a display panel according to an embodiment of the present disclosure;

FIG. 3 is a partial enlarged view of a further display panel according to an embodiment of the present disclosure;

FIG. 4 is a partial enlarged view of a further display panel according to an embodiment of the present disclosure;

FIG. 5 is a partial enlarged view of a further display panel according to an embodiment of the present disclosure;

FIG. 6 is a partial enlarged view of a further display panel according to an embodiment of the present disclosure;

FIG. 7 is a partial enlarged view of a further display panel according to an embodiment of the present disclosure;

FIG. 8 is a partial enlarged view of a further display panel according to an embodiment of the present disclosure;

FIG. 9 is a partial enlarged view of a further display panel according to an embodiment of the present disclosure;

FIG. 10 is a partial enlarged view of a further display panel according to an embodiment of the present disclosure; and

FIG. 11 is a schematic diagram of a structure of a display device according to an embodiment of the present disclosure.

### DETAILED DESCRIPTION OF EMBODIMENTS

To better understand the solutions of the present disclosure, the embodiments of the present disclosure will be clearly and completely described below with reference to the accompanying drawings for the embodiments of the present disclosure. Apparently, the described embodiments are merely some of, rather than all of, the embodiments of the present disclosure. On the basis of the embodiments of the present disclosure, all other embodiments which would have been obtained in the art without involving any inventive effort shall fall within the scope of protection of the present disclosure.

It should be noted that the terms such as “first” and “second” in the description and the claims of the present disclosure and in the aforementioned accompanying drawings are used to distinguish similar objects, and do not necessarily describe a specific order of precedence. It should be understood that the data used in this way can be interchanged where appropriate, so that the embodiments of the present disclosure described herein can be implemented in a sequence other than those illustrated or described herein. In addition, the terms “include” and “have” and any variation thereof are intended to cover a non-exclusive inclusion, for example, a process, method, system, product, or apparatus that includes a series of steps or units is not necessarily limited to those steps or units that are explicitly listed, but may include other steps or units not explicitly listed or inherent to such processes, methods, products or apparatuses.

The display panel in the related art has vertical stripes during display, and the inventors have found by careful researches that the reason for this problem is: fan-out lines in a display panel that need to be disposed in a non-active area are connected to signal lines that are disposed in an active area in order to transmit a drive signal to the signal lines. However, in the related art, there is a large resistance difference between two adjacent fan-out lines, causing the luminous brightness of two adjacent columns of sub-pixels to differ, and resulting in the phenomenon of visible vertical stripes.

For the problem described above, the present disclosure provides the following embodiments.

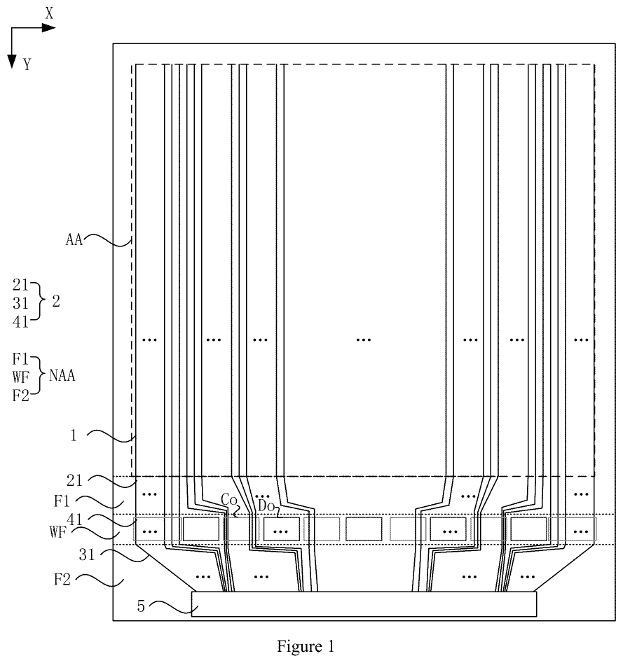

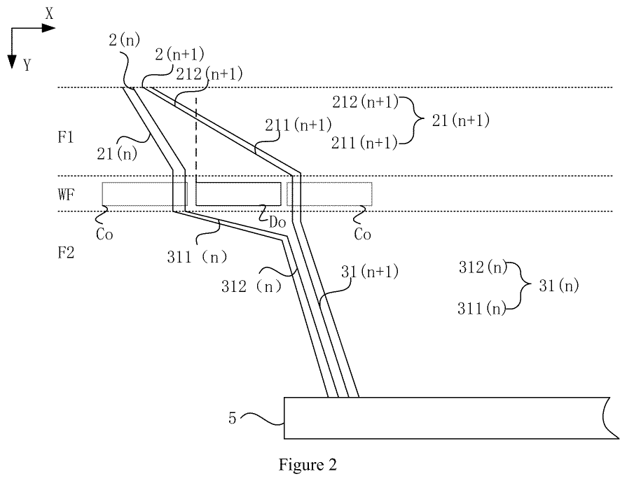

FIG. 1 is a schematic diagram of a structure of a display panel according to an embodiment of the present disclosure, and FIG. 2 is a partial enlarged view of a structure of a display panel according to an embodiment of the present disclosure. With reference to FIG. 1 and FIG. 2, the display panel includes an active area AA and a non-active area NAA arranged in a first direction Y, where the non-active area NAA includes a first fan-out area F1, a bending area WF, and a second fan-out area F2, which are sequentially away from the active area AA; and in the active area AA, provided are a plurality of first signal lines 1 extending in the first direction Y and arranged in a second direction X, the first direction Y intersecting the second direction X.

The non-active area NAA further includes a plurality of fan-out lines 2 electrically connected to the plurality of first signal lines 1, respectively; and the bending area WF includes a plurality of avoidance areas Do, and the fan-out lines 2 are arranged to avoid, which means not entering, being separated from, the avoidance areas Do.

In two fan-out lines 2 adjacent to the avoidance area Do in the second direction X and on different sides of the avoidance area Do, a section of one fan-out line 2 in the first fan-out area F1 includes a first extension segment and a second extension segment on a side of the first extension segment away from the bending area WF; a section of the other fan-out line 2 located in the second fan-out area F2 includes a first extension segment and a second extension segment located in a direction of the first extension segment away from the bending area WA; the first extension segments are configured to bypass a corresponding avoidance area Do in the second direction X; and the first extension segments of the two adjacent fan-out lines 2 on different sides of the avoidance area Do have the same line width, where the same line width is referred to here as being approximately the same, with some deviations possible due to process variations.

Specifically, the active area AA of the display panel is provided with a plurality of pixel drive circuits arranged in an array and sub-pixels, each pixel drive circuit being configured to drive at least one sub-pixel to emit light. The first direction Y may be a column direction, and the second direction X may be a row direction. A first signal line 1 is electrically connected to a column of pixel drive circuits, and the first signal line 1 is configured to supply a first signal to the pixel drive circuits to allow the pixel drive circuits to operate properly. For example, the first signal line 1 is, for example, a data line, a power signal line or an initialization signal line, etc. In this embodiment, the first signal line 1 is a data line by way of example.

As shown in FIG. 1, the second fan-out area F2 of the display panel is provided with a binding area 5, which is configured to bind a drive chip. The fan-out line 2 in the non-active area NAA is electrically connected at one end to a corresponding first signal line 1 and extends into the binding area 5 at the other end to be electrically connected to the drive chip. The drive chip outputs the first signal and outputs same to a corresponding pixel drive circuits through the fan-out line 2 and the corresponding first signal line 1. Each fan-out line includes a first section 21 located in the first fan-out area F1, a second section 31 located in the second fan-out area F2, and a third section 41 located in the bending area WF.

The non-active area NAA in this embodiment can be understood as a lower border area, and it will be appreciated of course that in the second direction X, the active area A A may also have non-active areas NAA on both sides. The second fan-out area F2 of the display panel can be bent to a back face of the display panel by means of the bending area WF, that is, a surface opposite a light-emitting surface.

The avoidance area Do in the bending area WF can be used to dispose other signal lines that are not electrically connected to the first signal lines. In some implementations, in the second direction X, the dimension of the avoidance area Do is greater than the maximum width of the fan-out line 2 and may be greater than one hundred times the maximum width of the fan-out line 2.

In this embodiment, the avoidance area Do is an avoidance area that does not overlap a centerline of the display panel, where the centerline is a centerline extending in the first direction Y. The two fan-out lines 2 each include a first extension segment and a second extension segment; and the first extension segments are the sections that bypass a corresponding avoidance area Do, thereby preventing the first extension segments from extending into the avoidance area in the second direction X. The second extension segments serve to extend the fan-out lines 2 in the first direction Y to enter the bending area WF. The first extension segments of the two fan-out lines 2 are located in different fan-out areas. The two fan-out lines 2 extend from the binding area 5 to the outside as a whole in a direction away from the above-mentioned centerline. From the perspective of the first direction Y, the section other than the first extension segment mainly contributes to the extension of the fan-out line from the first signal line 1 to the binding area; and from the perspective of the second direction X, the first extension segment mainly contributes to the fan-out line 2 bypassing the avoidance area Do. Moreover, the lengths of sections of the two fan-out lines 2 other than the first extension segments are the same or similar, and the lengths of the first extension segments are also the same or similar. In other words, in the two fan-out lines 2, excluding their respective first extension segments, the lengths of the sections located in the same fan-out area are the same or similar.

In the related art, the widths of the sections of all fan-out lines 2 in the first fan-out area F1 of the display panel are the same, the widths of the sections of all fan-out lines 2 in the second fan-out area F2 of the display panel are the same, and the widths of the fan-out lines in the first fan-out area F1 and the second fan-out area F2 are not the same. It will be appreciated that the size of the first fan-out area F1 is smaller, such that the border of the display panel is smaller, thus the widths of the fan-out lines in the first fan-out area F1 are less than the widths of the fan-out lines in the second fan-out area F2. However, as shown in FIG. 2, since the corresponding first extension segments of the two fan-out lines are located in different fan-out areas, the lengths of the sections of the two fan-out lines 2 located in the first fan-out area F1 are different, and the length difference is large; and the lengths of the sections of the two fan-out lines located in the second fan-out area F2 are also different, and the length difference is also large. However, the overall length difference between the two adjacent fan-out lines 2 is small. It can be approximately considered that the length difference between the sections of the two fan-out lines 2 in different fan-out areas corresponds to the length of the first extension segment in the fan-out area. In the related art, since the line width of the first extension segment is the same as that of other fan-out lines in the fan-out area, which results in a significant length difference in the sections with different line widths between the two adjacent fan-out lines 2. Consequently, this leads to a large resistance difference, causing the phenomenon of vertical stripes on the display panel during display. In other related art, in order to compensate for resistance differences, the section of the fan-out line 2 is arranged as a serpentine routing, which is arranged in the second fan-out area F2. This will result in the lengths of the sections with different line widths of different fan-out lines still being different, and during process variations, the variations in different line widths also differ, leading to different resistance differences in the different fan-out lines. Additionally, it also increases parasitic capacitance. That is, using the serpentine routing will still result in the phenomenon of vertical stripes.

In this embodiment, by providing the two fan-out lines 2, i.e. two fan-out lines 2 located on different sides of the avoidance area Do and adjacent to each other, two first extension segments of the two fan-out lines have the same line width, which ensures that the lengths of the sections with the same line width of the two fan-out lines are equal or approximately equal, thereby minimizing the resistance difference and avoiding the phenomenon of vertical stripes. Moreover, since the lengths of the sections with the same line width of the two fan-out lines are equal or approximately equal, even if there are resistance variations caused by process variations during manufacturing, these variations will be similar. This can relieve the vertical stripes caused by process variations, thereby enhancing the display effect.

According to some embodiments, a display panel is employed that includes an active area and a non-active area arranged in a first direction, where the non-active area includes a first fan-out area, a bending area, and a second fan-out area that are sequentially away from the active area; the active area includes a plurality of first signal lines extending in the first direction and arranged in a second direction, the first direction intersecting the second direction; the non-active area also includes a plurality of fan-out lines electrically connected to the plurality of first signal lines, respectively; a bending area is provided with a plurality of avoidance areas, and the fan-out lines avoid the avoidance areas; in two fan-out lines adjacent to the avoidance area in the second direction and on different sides of the avoidance area, a section of one fan-out line in a first fan-out area includes a first extension segment and a second extension segment connected to the first extension segment; a section of the other fan-out line in a second fan-out area includes a first extension segment and a second extension segment connected to the first extension segment; the first extension segments are configured to bypass a corresponding avoidance area in the second direction; and the first extension segments of the two adjacent fan-out lines on different sides of the avoidance area have the same line width. By setting the line widths of the two first extension segments to be equal such that the lengths of the sections with the same line width of the two fan-out lines on both sides of the avoidance area are similar or equal, so that the resistance difference between the two fan-out lines is small, and the difference in resistance variations caused by process variations during manufacturing is also small, which can thus greatly relieve the phenomenon of vertical stripes.

In one embodiment, the avoidance area Do is an avoidance area that does not overlap the centerline of the display panel, where the centerline is a centerline extending in the first direction Y. In an implementation, an included angle between the first extension segment and the second direction X is less than an included angle between the second extension segment and the second direction X, in that case the first extension segment is the section that bypasses the corresponding avoidance area Do. It will of course be appreciated that the first extension segment may be a straight line, and the included angle between the first extension segment and the second direction X may be less than or equal to a first preset included angle, which may be less than or equal to 45 degrees, such as 45 degrees, 30 degrees, or 15 degrees, etc. That is, the first extension segment mainly functions to shift the extension direction of the fan-out line in the second direction X to quickly bypass the corresponding avoidance area. The included angle between the second extension segment and the second direction X may be greater than or equal to a second preset included angle, which may be greater than or equal to 45 degrees, such as 45 degrees, 60 degrees, or 75 degrees, etc. The second extension segments mainly serve to extend the fan-out lines in the first direction Y to quickly enter the bending area. The first extension segments of the two fan-out lines are located in different fan-out areas. The two fan-out lines extend from the binding area 5 to the outside as a whole in a direction away from the above-mentioned centerline. From the perspective of the first direction Y, the section other than the first extension segment mainly contributes to the extension of the fan-out line 2 from the first signal line 1 to the binding area; and from the perspective of the second direction X, the first extension segment mainly contributes to the fan-out line 2 bypassing the avoidance area. Moreover, the lengths of sections of the two fan-out lines 2 other than the first extension segments are the same or similar, and the lengths of the first extension segments are also the same or similar. In other words, in the two fan-out lines 2, excluding their respective first extension segments, the lengths of the sections located in the same fan-out area are the same or similar.

In one embodiment, in some other implementations, such as when the first extension segment and the second extension segment are collinear, the first extension segment can be understood as the section of the fan-out line 2 in the fan-out area that overlaps an orthographic projection of the corresponding avoidance area Do in the first direction Y, and the second extension segment can be understood as the section of the fan-out line 2 in the fan-out area that does not overlap the orthographic projection of the corresponding avoidance area Do in the first direction Y.

In order to improve space utilization, it is possible to set the included angle between the first extension segment and the second direction X in at least one of the two fan-out lines 2 to be smaller than the included angle between the second extension segment and the second direction X. In addition, the length described herein is the same or close to allow for some tolerance. For example, the difference may be within 5% of the longer length.

In one embodiment, as shown in FIG. 2, each fan-out line 2 includes a first

extension segment, a second extension segment and a third extension segment; and the first extension segment functions to bypass the corresponding avoidance area Do in the second direction X, and each fan-out line 2 may include a plurality of first extension segments when the included angle between the first extension segment and the second direction X is smaller than the included angle between the second extension segment and the second direction X. It will be appreciated that a plurality of first extension segments of the same fan-out line 2 are located in the same fan-out area, and any two of these first extension segments can be either collinear or non-collinear. Similarly, the number of second extension segments can also be multiple. The first and second extension segments can be straight lines, which can make the overall length of the fan-out line 2 smaller compared with the arrangement of serpentine routing, thereby helping to reduce the resistance of the fan-out line 2. The third extension segment is the section of the fan-out line 2 that is located in a different fan-out area than the first extension segment. In this embodiment, among the sections other than all the first extension segments in all the fan-out lines, the line widths of the sections located in the same fan-out area are the same, and the line widths of the sections located in different fan-out areas are different. Moreover, it is possible to set the line width of the section located in the second fan-out area F2 to be greater than the line width of the section located in the first fan-out area F1.

For example, as shown in FIG. 2, in some implementations, two fan-out lines are provided adjacent to the avoidance area Do in the second direction X and on different sides of the avoidance area Do, the section of the first fan-out line 2 (n+1) located in the first fan-out area F1 includes a first extension segment 211 (n+1) and a second extension segment 212 (n+1), and the section of the second fan-out line 2 (n) located in the second fan-out area F2 includes a first extension segment 311 (n) and a second extension segment 312 (n), where the first fan-out line 2 (n+1) is a fan-out line close to the center of the bending area WF, and the second fan-out line 2 (n) is a fan-out line away from the centerline of the bending area.

Specifically, in this embodiment, the first extension segment 311 (n) of the second fan-out line 2 (n) is disposed in the second fan-out area F2, and the first extension segment 311 (n+1) of the first fan-out line 2 (n+1) is disposed in the first fan-out area F1. In this arrangement, the two fan-out lines 2 do not need to cross to bypass the avoidance area Do and can connect to the corresponding first signal line 1. That is, different fan-out lines 2 can be located in the same film layer, avoiding cross-talk of signals. Of course, in some other implementations, the first extension segment 311 (n) of the second fan-out line 2 (n) may also be disposed in the first fan-out area F1, and the first extension segment 311 (n+1) of the first fan-out line 2 (n+1) is disposed in the second fan-out area F2. In this arrangement, in the second direction X, since a pin corresponding to the first fan-out line in the binding area is located on the side of a pin corresponding to the second fan-out line that is close to the center of the display panel, and the first signal line 1 corresponding to the first fan-out line is also located on the side of the pin corresponding to the second fan-out line close to the center of the display panel, the first fan-out line and the second fan-out line inevitably overlap, but a bridge can be provided at the overlap to prevent the two from short-circuiting.

It should also be noted that although the second extension segment 312 (n) of the second fan-out line 2 (n) in FIG. 2 is connected between the binding area 5 and the first extension segment 311 (n), the present disclosure is not limited thereto. The first extension segment 311 (n) of the second fan-out line 2 (n) may also be connected between the binding area 5 and the second extension segment 312 (n).

In one embodiment, in some implementations, as shown in FIG. 2, the first extension segment 211 (n+1) of the first fan-out line 2 (n+1) is collinear with the corresponding second extension segment 212 (n+1), and an included angle between the first extension segment 311 (n) of the second fan-out line 2 (n) and the second direction X is smaller than an included angle between the corresponding second extension segment 312 (n) and the second direction X.

Specifically, in this embodiment, the section of the fan-out line in the first fan-out area F1 is linear, and the section of the first fan-out line in the second fan-out area F2 is zigzag; the second extension segment 212 (n+1) of the first fan-out line 2 (n+1) is similar in length and equal in line width to the third extension segment 21 (n) of the second fan-out line 2 (n); the first extension segment 211 (n+1) of the first fan-out line 2 (n+1) is similar in length and equal in line width to the first extension segment 311 (n) of the second fan-out line 2 (n); and the third extension segment 31 (n+1) of the first fan-out line 2 (n+1) is similar in length and equal in line width to the second extension segment 312 (n) of the second fan-out line 2 (n). Therefore, the lengths of the sections with the same line width of the first fan-out line 2 (n+1) and the second fan-out line 2 (n) are similar, which can reduce the difference in impedance, and the difference in resistance variations caused by process variations during manufacturing is smaller, thereby further reducing the difference in impedance in the actual finished product, and relieving the phenomenon of vertical stripes.

In one embodiment, as shown in FIG. 2, the third extension segment 31 (n+1) of the first fan-out line 2 (n+1) extends parallel to the second extension segment 312 (n) of the second fan-out line 2 (n). This arrangement makes the length difference between the two smaller. It is further possible to set the length difference between the third extension segment 31 (n+1) of the first fan-out line 2 (n+1) and the second extension segment 312 (n) of the second fan-out line 2 (n) to be smaller than or equal to a first preset value, the preset value mentioned in the description being a conventional value according to the product in the prior art. The first preset value is 5% of the length of the third extension segment 31 (n+1) of the first fan-out line 2 (n+1), so that the length difference between the first fan-out line and the second fan-out line in different fan-out areas is closer to the length of a corresponding first extension segment, and the resistance difference between the first fan-out line and the second fan-out line can be further reduced by setting the line width of the corresponding first extension segments to be the same.

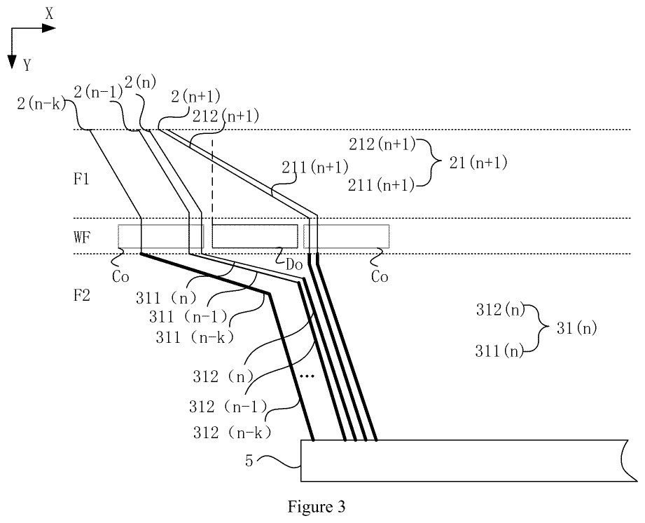

In one embodiment, FIG. 3 is a partial enlarged view of a further display panel according to an embodiment of the present disclosure, and with respect to FIGS. 1 and 3, a plurality of fan-out lines include a plurality of first progressive fan-out lines sequentially disposed on a side of the second fan-out line 2 (n) away from a centerline of the bending area WF, where the centerline is a centerline extending in the first direction Y and in the center of the bending area WF in the second direction X. Each first progressive fan-out line includes a first extension segment and a second extension segment located in the second fan-out area F2, and an included angle between the first extension segment and the second direction X is smaller than an included angle between the second extension segment and the second direction X. In a plurality of first extension segments of the second fan-out line corresponding to the plurality of first progressive fan-out lines, the width of the first extension segments gradually increases in a direction away from the centerline of the bending area.

Specifically, the bending area WF of the display panel includes hub areas Co and an avoidance area Do spaced apart from each other in the second direction X, and the sections of the fan-out lines 2 of the display panel that are located in the bending area WF are located within a respective hub area Co, that is, each hub area Co corresponds to a plurality of fan-out lines 2. In the plurality of fan-out lines corresponding to the same hub area Co, the fan-out line closest to the centerline (i.e. the above-mentioned centerline of the bending area) of the display panel is the second fan-out line corresponding to the avoidance area Do close to the center of the display panel, and the right-most fan-out line in the first hub area Co from left to right as shown in FIG. 3 is the second fan-out line corresponding to the avoidance area Do; and the fan-out line furthest from the centerline of the display panel is the first fan-out line corresponding to the avoidance area Do away from the centerline of the display panel, and as shown in FIG. 3, the left-most fan-out line in the second hub area CO from left to right is the first fan-out line corresponding to the avoidance area Do. In other words, the first and second fan-out lines corresponding to the avoidance area Do correspond to different hub areas, while the first and second fan-out lines corresponding to different avoidance areas exist in the same hub area. As shown in FIG. 3, in the plurality of fan-out lines corresponding to the same fan-out area, a plurality of first progressive fan-out lines are included, and are sequentially labeled as 2 (n−1), . . . , 2(n−k) in the direction of the second fan-out line 2 (n) away from the centerline of the bending area, where k is an integer greater than or equal to 2. Since the first progressive fan-out line is close to the corresponding second fan-out line, each first progressive fan-out line still needs to be provided with a first extension segment to quickly bypass the corresponding avoidance area (which is the same as the avoidance area corresponding to the second fan-out line) in the second direction, the included angle between the first extension segment and the second direction X may also be less than or equal to the first preset included angle, the included angle between the second extension segment and the second direction X may also be greater than or equal to the second preset included angle, and the relevant features of the first extension segment and the second extension segment in the first progressive fan-out line may refer to the relevant features of the first extension segment and the second extension segment in the first fan-out line, which will not be described here. It is of course to be noted that for the fan-out lines arranged in sequence on one side of the centerline of the display panel, there are a plurality of second progressive fan-out lines, that is to say, in addition to the first and second fan-out lines, the same hub area includes a plurality of first and second progressive fan-out lines, and the closest first and second progressive fan-out lines may have other fan-out lines therebetween. The number of the first progressive fan-out lines and the number of the second progressive fan-out lines in each hub area can be equal or unequal. The section of the second progressive fan-out line in the second fan-out area does not need to be provided with first and second extension segments to bypass the avoidance area, for example only the third extension segment may be provided to extend from a position corresponding to the binding area to a position corresponding to the hub area Co, but after extension to the first fan-out area F1, a first extension segment and a second extension segment need to be provided in the first fan-out area F1 to bypass the corresponding avoidance area Do to connect with the corresponding first signal line 1.

In a plurality of first progressive fan-out lines corresponding to the same hub area Co, the length of the first extension segment of each first progressive fan-out line is similar, the length of the second extension segment is also similar, and the length of the third extension segment (the section of the first progressive fan-out line in the first fan-out area F1) is also similar. It is clear from the above analysis that in the second fan-out area F2, the sections of all fan-out lines 2 (including the first fan-out line, the second fan-out line, and the first progressive fan-out line) have the same line width (the line width may be defined, for example, as a first line width) except for all the first extension segments. If the first extension segment of the first progressive fan-out line is set to the first line width, there will be some resistance differences between the second fan-out line and the first progressive fan-out line adjacent thereto, and there will be a certain phenomenon of vertical stripes. In this embodiment, the line width of the first extension segment in the first progressive fan-out line is set to be the progressive line width, that is, the line width of the first extension segment labeled as 311 (n−1) is smaller than the line width of the first extension segment labeled as 311 (n), . . . and so on. This arrangement can reduce the resistance difference between the two adjacent fan-out lines 2, thus further relieving the phenomenon of vertical stripes.

Still further, the line width of the first extension segment of the second fan-out line is smaller than the first line width, and the maximum line width of the first extension segment of the first progressive fan-out line is set to be equal to the first line width; and the difference between the line widths of corresponding first extension segments of any two adjacent first progressive fan-out lines is equal. In other words, in the first extension segments corresponding to the first fan-out line and the plurality of first progressive fan-out lines, the line width of the first extension segment is uniformly increased, so that the resistance difference between the first progressive fan-out line and the fan-out line adjacent thereto is small, and the impact of process variations on the resistance variations of different fan-out lines is relatively consistent, which can prevent excessive resistance differences between two adjacent fan-out lines and thus avoid the phenomenon of vertical stripes. Moreover, the maximum value is the first line width, and the minimum value is the line width of the first extension segment corresponding to the first fan-out line; and the maximum line width is equal to the first line width, which can save space in the second fan-out area F2 compared with a design where the line width of each of the first extension segments is the first line width. In addition, the minimum line width of the fan-out line 2 is the line width of the first extension segment of the first fan-out line, and the maximum resistance is small. At the same time, since the length of the fan-out line is not increased by using serpentine routing or other methods, the parasitic capacitance will not increase.

It should be noted that the second extension segment of the first progressive fan-out line labeled as 2 (n−1) in FIG. 3 is labeled as 312 (n−1), and the second extension segment of the first progressive fan-out line labeled as 2 (n−k) is labeled as 312 (n−k).

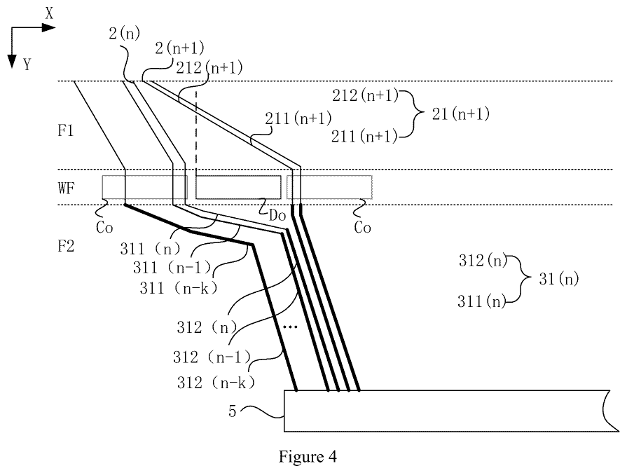

It should be noted that, as shown in FIG. 4, FIG. 4 is a partial enlarged view of a further display panel according to an embodiment of the present disclosure. In the first progressive fan-out line and the second fan-out line, either fan-out line may include at least two first extension segments, and different first extension segments in the same fan-out line may or may not be parallel, but both satisfy the relationship with the second extension segment as described above.

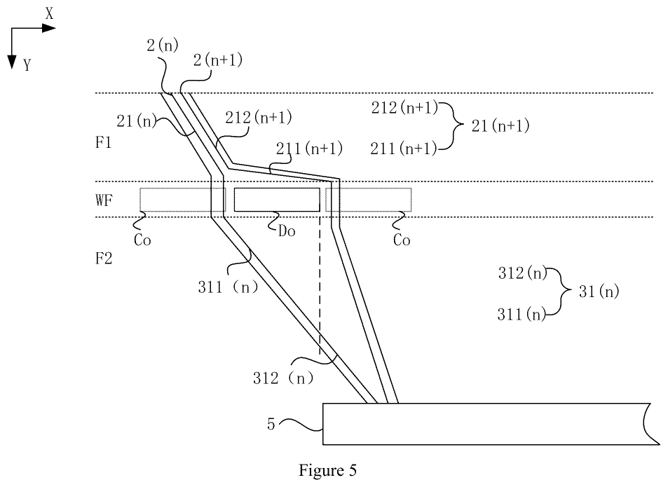

In some other implementations, FIG. 5 is a partial enlarged view of a further display panel according to an embodiment of the present disclosure. With reference to FIGS. 1 and 5, unlike the embodiment shown in FIG. 2, in this embodiment, an included angle between the first extension segment of the first fan-out line 2 (n+1) and the second direction X is smaller than an included angle between a corresponding second extension segment and the second direction X; and the first extension segment of the second fan-out line 2 (n) is collinear with the corresponding second extension segment.

Specifically, in this embodiment, the section of the fan-out line in the second fan-out area F2 is linear, and the section of the second fan-out line in the first fan-out area F1 is zigzag; the second extension segment 212 (n+1) of the first fan-out line 2 (n+1) is similar in length and equal in line width to the third extension segment of the second fan-out line 2 (n); the first extension segment 211 (n+1) of the first fan-out line 2 (n+1) is similar in length and equal in line width to the first extension segment 311 (n) of the second fan-out line 2 (n); and the third extension segment 31 (n+1) of the first fan-out line 2 (n+1) is similar in length and equal in line width to the second extension segment 312 (n) of the second fan-out line 2 (n). Therefore, the lengths of the sections with the same line width of the first fan-out line 2 (n+1) and the second fan-out line 2 (n) are similar, which can reduce the difference in impedance, and the difference in resistance variations caused by process variations during manufacturing is smaller, thereby further reducing the difference in impedance in the actual finished product, and relieving the phenomenon of vertical stripes. In this embodiment, the provision of the zigzag fan-out line in the first fan-out area F1 can improve space utilization in the first fan-out area F1, thereby helping to reduce the lower border of the display panel.

In one embodiment, as shown in FIG. 5, the second extension segment 212 (n+1) of the first fan-out line 2 (n+1) extends parallel to the third extension segment 21 (n) of the second fan-out line 2 (n). This arrangement makes the length difference between the two smaller. It is further possible to set the length difference between the second extension segment 212 (n+1) of the first fan-out line 2 (n+1) and the third extension segment 21 (n) of the second fan-out line 2 (n) to be smaller than or equal to a second preset value, and the second preset value is 5% of the length of the third extension segment 21 (n) of the second fan-out line 2 (n), so that the length difference between the first fan-out line and the second fan-out line in different fan-out areas is closer to the length of the corresponding first extension segment, and the resistance difference between the first fan-out line and the second fan-out line can be further reduced by setting the line width of the corresponding first extension segment to be the same.

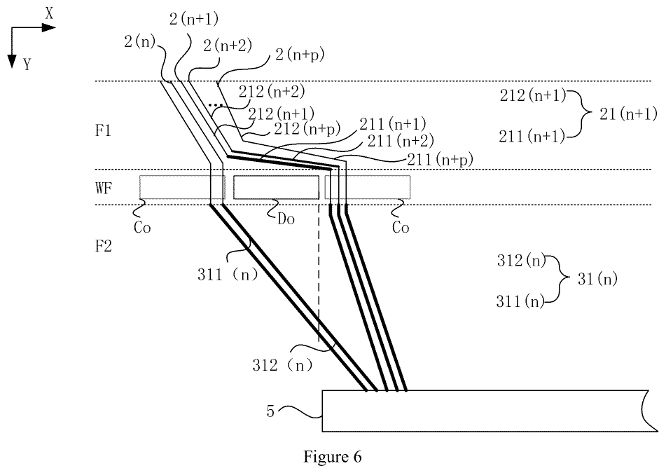

In one embodiment, FIG. 6 is a partial enlarged view of a further display panel according to an embodiment of the present disclosure. With reference to FIGS. 1 and 6, the plurality of fan-out lines 2 include a plurality of second progressive fan-out lines arranged in sequence on the side of the first fan-out line 2 (n+1) close to the center of the bending area WF. Each second progressive fan-out line includes a first extension segment and a second extension segment located in the first fan-out area F1. In the first extension segments corresponding to the first fan-out line and the plurality of second progressive fan-out lines, the widths of different first extension segments gradually decrease in a direction close to the centerline of the bending area.

Specifically, in the plurality of fan-out lines corresponding to the same fan-out area, a plurality of second progressive fan-out lines are included, and are sequentially labeled as 2 (n+2), . . . , 2 (n+p) in the direction of the first fan-out line 2 (n+1) close to the centerline of the bending area, where p is an integer greater than or equal to 3. Since the second progressive fan-out line is close to the corresponding first fan-out line, each first progressive fan-out line still needs to be provided with a first extension segment to quickly bypass the corresponding avoidance area (which is the same as the avoidance area corresponding to the second fan-out line) in the second direction, the included angle between the first extension segment and the second direction X may also be less than or equal to the first preset included angle, the included angle between the second extension segment and the second direction X may also be greater than or equal to the second preset included angle, and the relevant features of the first extension segment and the second extension segment in the second progressive fan-out line may refer to the relevant features of the first extension segment and the second extension segment in the first fan-out line, which will not be described here. It is of course to be noted that for the fan-out lines arranged in sequence on one side of the centerline of the display panel, there are a plurality of first progressive fan-out lines, that is to say, in addition to the first and second fan-out lines, the same hub area includes a plurality of first and second progressive fan-out lines, and the closest first and second progressive fan-out lines may have other fan-out lines therebetween. The number of the first progressive fan-out lines and the number of the second progressive fan-out lines in each hub area Co can be equal or unequal. The section of the first progressive fan-out line in the first fan-out area F1 does not need to be provided with first and second extension segments to bypass the avoidance area, for example only the third extension segment may be provided to extend from a position corresponding to the binding area to a position corresponding to the hub area Co, but in the second fan-out area F2, a first extension segment and a second extension segment need to be provided to bypass the corresponding avoidance area to connect with the corresponding first signal line 1.

In a plurality of second progressive fan-out lines corresponding to the same hub area Co, the length of the first extension segment of each first progressive fan-out line is similar, the length of the second extension segment is also similar, and the length of the third extension segment (the section of the second progressive fan-out line in the second fan-out area F2) is also similar. It is clear from the above analysis that in the first fan-out area, the sections of all fan-out lines 2 (including the first fan-out line, the second fan-out line, and the first progressive fan-out line) have the same line width (the line width may be defined, for example, as a second line width) except for all the first extension segments. If the first extension segment of the second progressive fan-out line is set to the second line width, there will be some differences in resistance between the first fan-out line and the second progressive fan-out line adjacent thereto, and there will be a certain phenomenon of vertical stripes. In this embodiment, the line width of the first extension segment in the second progressive fan-out line is set to be the progressive line width, that is, the line width of the first extension segment labeled as 212 (n+1) is greater than the line width of the first extension segment labeled as 212 (n+2), . . . and so on. This arrangement can reduce the resistance difference between the two adjacent fan-out lines, thus further relieving the phenomenon of vertical stripes.

Further, the line width of the first extension segment of the first fan-out line is greater than the second line width, and the minimum line width of the first extension segment of the second progressive fan-out line is set to be equal to the second line width; and the difference between the line widths of corresponding first extension segments of any two adjacent second progressive fan-out lines is equal. In other words, in the first extension segments corresponding to the second fan-out line and the plurality of second progressive fan-out lines, the line width of the first extension segment is uniformly decreased, so that the resistance difference between the second progressive fan-out line and the fan-out line adjacent thereto is small, and the impact of process variations on the resistance variations of different fan-out lines is relatively consistent, which can prevent excessive resistance differences between two adjacent fan-out lines and thus avoid the phenomenon of vertical stripes. Moreover, the minimum value is the second line width, and the maximum value is the line width of the first extension segment corresponding to the first fan-out line; and the minimum line width is equal to the second line width, which can reduce the resistance of the second progressive fan-out line compared with a design where the line width of each of the first extension segments is the second line width. In addition, the minimum line width of the fan-out line is the line width of the first extension segment of the first fan-out line, and the maximum resistance is small. At the same time, since the length of the fan-out line is not increased by using serpentine routing or other methods, the parasitic capacitance will not increase.

It should be noted that the second extension segment of the second progressive fan-out line labeled as 2 (n+2) in FIG. 3 is labeled as 212 (n+2), and the second extension segment of the second progressive fan-out line labeled as 2 (n+p) is labeled as 212 (n+p).

It is of course to be noted that the embodiment shown in FIG. 3 is more preferred due to the space limitation of the first fan-out area F1.

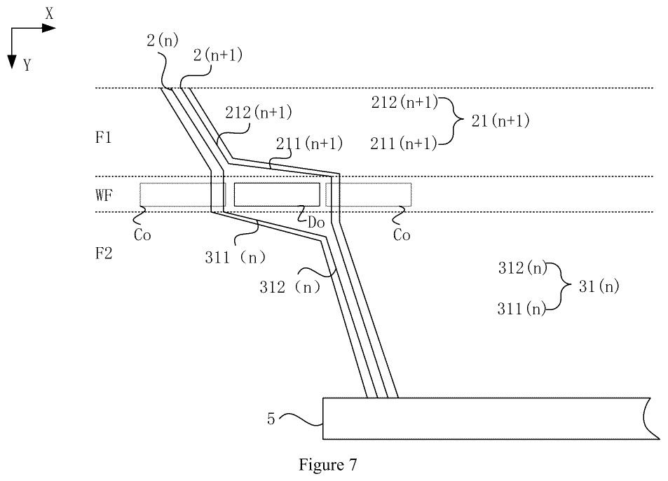

In one embodiment, FIG. 7 is a partial enlarged view of a further display panel according to an embodiment of the present disclosure. With reference to FIGS. 1 and 7, in this embodiment, an included angle between the first extension segment 211 (n+1) of the first fan-out line 2 (n+1) and the second direction is smaller than an included angle between a corresponding second extension segment 212 (n+1) and the second direction; and an included angle between the first extension segment 311 (n) of the second fan-out line 2 (n) and the second direction X is smaller than an included angle between a corresponding second extension segment 312 (n) and the second direction X.

In particular, the first extension segment and the corresponding second extension segment of the first fan-out line in this embodiment are not collinear, and the corresponding first extension segment and the corresponding second extension segment of the second fan-out line are also not collinear, as compared with the above-described embodiment with a collinear configuration, the space utilization of the first fan-out area F1 and the second fan-out area F2 can be higher.

In one embodiment, the third extension segment 31 (n+1) of the first fan-out line 2 (n+1) extends parallel to the second extension segment 312 (n) of the second fan-out line 2 (n). In one embodiment, the length difference between the third extension segment 31 (n+1) of the first fan-out line 2 (n+1) and the second extension segment 312 (n) of the second fan-out line 2 (n) is less than or equal to a fourth preset value, the fourth preset value being 5% of the length of the third extension segment 31 (n+1) of the first fan-out line 2 (n+1). In one embodiment, the second extension segment 212 (n+1) of the first fan-out line 2 (n+1) extends parallel to the third extension segment 21 (n) of the second fan-out line 2 (n). In one embodiment, the length difference between the second extension segment 212 (n+1) of the first fan-out line 2 (n+1) and the third extension segment 21 (n) of the second fan-out line 2 (n) is less than or equal to a fourth preset value, the fourth preset value being 5% of the length of the third extension segment 21 (n) of the second fan-out line 2 (n). The beneficial effects described above may be referred to as previously described and will not be repeated here.

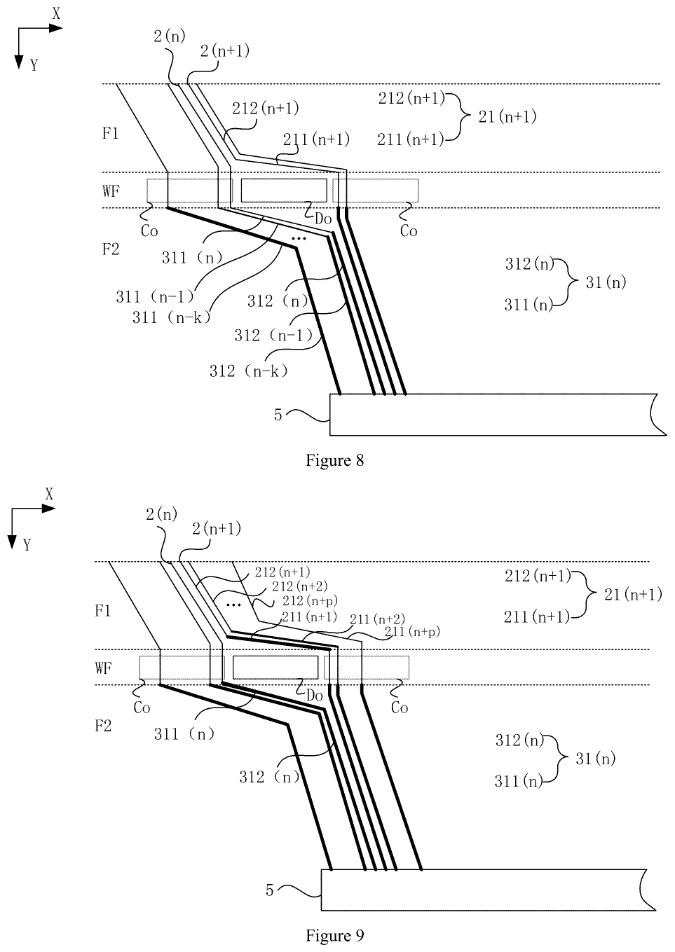

In one embodiment, FIG. 8 is a partial enlarged view of a further display panel according to an embodiment of the present disclosure. With reference to FIGS. 1 and 8, a plurality of fan-out lines include a plurality of first progressive fan-out lines sequentially disposed on the side of the second fan-out line 2 (n) away from the center of the bending area WF. Each first progressive fan-out line includes a first extension segment and a second extension segment located in the second fan-out area F2, and the included angle between the first extension segment and the second direction X is smaller than the included angle between the second extension segment and the second direction X. In a plurality of first extension segments of the second fan-out line corresponding to the plurality of first progressive fan-out lines, the width of the first extension segments gradually increases in a direction away from the centerline of the bending area. The line width of all sections of the fan-out lines located in the second fan-out area, except for all the first extension segments, is the first line width; the line width of a section of the fan-out line located in the first fan-out area is the second line width; the line width of the first extension segment of the second fan-out line is smaller than the first line width, and the maximum line width of the first extension segment of the first progressive fan-out line is set to be equal to the first line width; and the difference between the line widths of corresponding first extension segments of any two adjacent first progressive fan-out lines is equal. The beneficial effects of this embodiment may be referred to in the description of FIG. 3 in this document and will not be repeated here.

In one embodiment, in some other implementations, FIG. 9 is a partial enlarged view of a further display panel according to an embodiment of the present disclosure. With reference to FIGS. 1 and 9, the plurality of fan-out lines include a plurality of second progressive fan-out lines arranged in sequence on the side of the first fan-out line 2 (n+1) close to the centerline of the bending area WF. Each second progressive fan-out line includes a first extension segment and a second extension segment located in the first fan-out area F1. In the first extension segments corresponding to the first fan-out line and the plurality of second progressive fan-out lines, the widths of different first extension segments gradually decrease in a direction close to the centerline of the bending area. The line width of all sections of the fan-out lines located in the first fan-out area, except for all the first extension segments, is the second line width; the line width of the section of the fan-out line located in the second fan-out area is the first line width; the line width of the first extension segment of the first fan-out line is greater than the second line width, and the minimum line width of the first extension segment of the second progressive fan-out line is set to be equal to the second line width; and the difference between the line widths of corresponding first extension segments of any two adjacent second progressive fan-out lines is equal. The beneficial effects of this embodiment may be referred to in the description of FIG. 6 in this document and will not be repeated here. It should be noted that for the embodiment shown in FIG. 8 and FIG. 9, since the size of the first fan-out area F1 required for the embodiment shown in FIG. 8 is small, the embodiment shown in FIG. 8 is more preferable.

In one embodiment, as shown in FIG. 7, the first extension segment 211 (n+1) of the first fan-out line 2 (n+1) extends parallel to the first extension segment 311 (n+1) of the second fan-out line 2 (n). With such arrangement, the length difference between the sections of the first and second fan-out lines in different fan-out areas is closer to the difference in the corresponding first extension segment, so that by setting the line width of the first extension segment, the effect of better reducing the resistance difference can be achieved.

In one embodiment, the first extension segments of the first progressive fan-out lines extend parallel to each other, and extend parallel to the first extension segment of the corresponding second fan-out line.

In one embodiment, the first extension segments of the second progressive fan-out lines extend parallel to each other, and extend parallel to the first extension segment of the corresponding first fan-out line.

In one embodiment, with reference to FIG. 1, in some implementations, a plurality of second signal lines (not shown) are also arranged within the active area AA, and a plurality of direct-current signal lines are arranged in the avoidance area Do, the direct-current signal lines being electrically connected to the second signal lines.

Specifically, the active area may include pixel drive circuits arranged in an array in the first direction Y and the second direction X, the first signal line 1 being configured to supply a data signal to the pixel drive circuits; that is, the first signal line is a data line; and the pixel drive circuits in the same line in the first direction are electrically connected to the same first signal line. The pixel drive circuit may be a pixel drive circuit including two transistors and one capacitor, which may be referred to as a “2T1C” pixel drive circuit; and it may also be a pixel drive circuit including four transistors and one capacitor, or a pixel drive circuit including seven transistors and one capacitor, and the like, and an embodiment of the present disclosure is not limited thereto. The specific structure and working principle of the pixel drive circuit are well known to in the art and will not be described here in detail. The first signal line is a data line, the second signal line may be a direct-current signal line providing a power signal. The direct-current signal line, for example, may be a power signal line providing a high level or a direct-current signal line providing a low level. More specifically, two adjacent avoidance areas may be provided with different direct-current signal lines, such as one with a high level direct-current signal line and the other with a low level direct-current signal line.

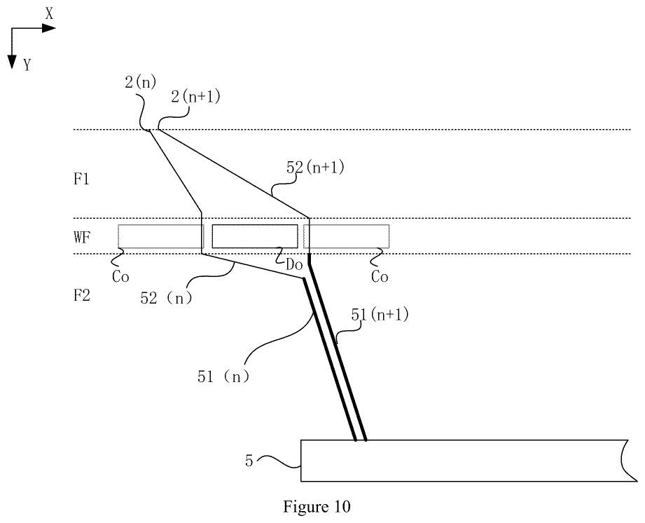

An embodiment of the present disclosure further provides a display panel, FIG. 10 is a partial enlarged view of a further display panel according to the embodiment of the present disclosure. With reference to FIGS. 1 and 10, the display panel includes an active area A A and a non-active area NAA arranged in a first direction Y, where the non-active area NAA includes a first fan-out area F1, a bending area WA, and a second fan-out area F2, which are sequentially away from the active area AA; and the active area AA is provided with a plurality of first signal lines 1 extending in the first direction Y and arranged in a second direction Y, the first direction Y intersecting the second direction X.

The non-active area NAA further includes a plurality of fan-out lines 2 electrically connected to the plurality of first signal lines 1, respectively; and the bending area WA includes a plurality of avoidance areas Do, and the fan-out lines 2 avoid the avoidance areas Do.

The two fan-out lines 2, which are adjacent to the avoidance area Do in the second direction X and on different sides of the avoidance area Do, are equal in length and both include a first line width segment and a second line width segment, the first line width segments of the two fan-out lines have the same line width and length, and the second line width segments of the two fan-out lines have the same line width and length.

Specifically, the two fan-out lines on both sides of the avoidance area Do are set to be the first fan-out line 2 (n) and the second fan-out line 2 (n+1), respectively, the first line width segment of the first fan-out line 2 (n) being 51 (n) and the second line width segment being 52 (n). The first line width segment of the second fan-out line 2 (n+1) is 51 (n+1), and the second line width segment is 52 (n+1). The line width of the first line width segment is different from the line width of the second line width segment, and in the related art, the length of the first line width segment is different, and the length of the second line width segment is also different. However, the total length of the first and second fan-out lines is approximately equal, resulting in the resistance of the first and second fan-out lines being different, and causing the phenomenon of vertical stripes.

In this embodiment, the length of the first line width segment of the first fan-out line is set to be equal to the length of the first line width segment of the second fan-out line, and the length of the second line width segment of the first fan-out line is set to be equal to the length of the second line width segment of the second fan-out line, so that the lengths of different line widths in the first fan-out line and the second fan-out line are equal, thereby enabling the resistance of the first and second fan-out lines to be the same, and relieving the phenomenon of vertical stripes. Moreover, the resistance variations caused by process variations during manufacturing are also similar, thereby further reducing the resistance difference.

According to some embodiments, a display panel is employed that includes an active area and a non-active area arranged in a first direction, where the non-active area includes a bending area; the active area includes a plurality of first signal lines extending in the first direction and arranged in a second direction, the first direction intersecting the second direction; the non-active area also includes a plurality of fan-out lines electrically connected to the plurality of first signal lines, respectively; a bending area is provided with a plurality of avoidance areas, and the fan-out lines avoid the avoidance areas; and two fan-out lines, which are adjacent to the avoidance area in the second direction and on different sides of the avoidance area, are equal in length and both include a first line width segment and a second line width segment, the first line width segments of the two fan-out lines have the same line width and length, and the second line width segments of the two fan-out lines have the same line width and length. The length of the first line width segment of the first fan-out line is set to be equal to the length of the first line width segment of the second fan-out line, and the length of the second line width segment of the first fan-out line is set to be equal to the length of the second line width segment of the second fan-out line, so that the lengths of different line widths in the first fan-out line and the second fan-out line are equal, thereby enabling the resistance of the first and second fan-out lines to be the same, and relieving the phenomenon of vertical stripes.

It will be appreciated that the equal line widths allow for a tolerance within 5%, and the equal lengths also allow for a tolerance within 5%.

In one embodiment, with reference to FIGS. 1 and 2, the non-active area NAA includes a first fan-out area F1, a bending area WF, and a second fan-out area F2, which are sequentially away from the active area AA. In an implementation, an included angle between the first extension segment and the second direction X is less than an included angle between the second extension segment and the second direction X. In some other implementations, such as when the first extension segment and the second extension segment are collinear, the first extension segment can be understood as the section of the fan-out line in the fan-out area that overlaps an orthographic projection of the corresponding avoidance area in the first direction Y, and the second extension segment can be understood as the section of the fan-out line in the fan-out area that does not overlap the orthographic projection of the corresponding avoidance area Do in the first direction Y. Two fan-out lines are provided adjacent to the avoidance area Do in the second direction X and on different sides of the avoidance area Do, the section of the first fan-out line 2 (n+1) located in the first fan-out area F1 includes a first extension segment 211 (n+1) and a second extension segment 212 (n+1), and the section of the second fan-out line 2 (n) located in the second fan-out area F2 includes a first extension segment 311 (n) and a second extension segment 312 (n), where the first fan-out line 2 (n+1) is a fan-out line close to the centerline of the bending area WF, and the second fan-out line 2 (n) is a fan-out line away from the centerline of the bending area WF. In addition, the section of the first fan-out line in the second fan-out area F2 includes a third extension segment, and the section of the second fan-out line in the first fan-out area includes a third extension segment.

In an implementation, as shown in FIGS. 2 and 10, the second line width segment of the first fan-out line includes a corresponding first extension segment and a corresponding second extension segment; the first line width segment of the first fan-out line includes a corresponding third extension segment; the second line width segment of the second fan-out line includes a corresponding third extension segment and a corresponding first extension segment; and the first line width segment of the second fan-out line includes a corresponding second extension segment. More specifically, the line width of the first fan-out area F1 in the display panel is the second line width except for the line width of the first extension segment, and the line width of the second fan-out area F2 is the first line width except for the line width of the first extension segment. The first line width segment of the first fan-out line includes a second extension segment, and the first line width segment includes all sections except for the second extension segment and the bending area, i.e., including the first extension segment and the third extension segment. The first line width segment of the second fan-out line includes a section located in the second fan-out area, i.e., including a third extension segment, and the second line width segment includes a section located in the first fan-out area, i.e., including a first extension segment and a second extension segment. This arrangement allows the lengths of different line width segments in the first and second fan-out lines to be equal, thus reducing the resistance difference and relieving the phenomenon of vertical stripes during display.

In one embodiment, the width of the first line width segment in the fan-out line is greater than the width of the corresponding second line width segment. Most of the fan-out lines in the first fan-out area have a second line width, and most of the fan-out lines in the second fan-out area have a first line width. The arrangement of this embodiment allows the space required for the first fan-out area to be smaller, thereby reducing the border of the display panel.

In one embodiment, in conjunction with FIGS. 1 and 3, a plurality of fan-out lines include a plurality of first progressive fan-out lines sequentially disposed on the side of the second fan-out line 2 (n) away from the center of the bending area WF. Each first progressive fan-out line includes a first extension segment and a second extension segment located in the second fan-out area F2, and the included angle between the first extension segment and the second direction X is smaller than the included angle between the second extension segment and the second direction X. In a plurality of first extension segments of the second fan-out line corresponding to the plurality of first progressive fan-out lines, the width of the first extension segments gradually increases in a direction away from the centerline of the bending area. Still further, the line width of the first extension segment of the second fan-out line is smaller than the first line width, and the maximum line width of the first extension segment of the first progressive fan-out line is set to be equal to the first line width; and the difference between the line widths of corresponding first extension segments of any two adjacent first progressive fan-out lines is equal. In addition, it should be noted that the lengths of the two adjacent fan-out lines are equal. This embodiment is arranged such that, from the first progressive fan-out lines and the second fan-out line, the resistance difference between two adjacent fan-out lines is small, and the difference in resistance variations caused by process variations during manufacturing is also small, which can relieve the phenomenon of vertical stripes. It should be noted that the first line width segment in the first progressive fan-out line is the corresponding second extension segment.

In one embodiment, in another implementation, with reference to FIG. 6 or FIG. 9, the first line width segment of the first fan-out line includes a corresponding first extension segment and a corresponding second extension segment; the second line width segment of the first fan-out line includes a corresponding third extension segment; the second line width segment of the second fan-out line includes a corresponding second extension segment and a corresponding first extension segment; and the first line width segment of the second fan-out line includes a corresponding third extension segment. In this embodiment, the widths of all the fan-out lines in the second fan-out area are equal and each are the first line width; and the line widths in the first fan-out area are equal except for all the first extension segments, and each are the second line width. The line width of the first extension segment of the second fan-out line is the first line width, which can make the resistance difference between the first fan-out line and the second fan-out line small, thereby relieving the phenomenon of vertical stripes.

In one embodiment, the plurality of fan-out lines include a plurality of second progressive fan-out lines disposed sequentially on the side of the first fan-out line close to the centerline of the bending area. each of the second progressive fan-out lines includes a first extension segment and a second extension segment located in the first fan-out area; in the first extension segments of the first fan-out line corresponding to the plurality of second progressive fan-out lines, the widths of different first extension segments gradually decrease in a direction close to the centerline of the bending area; preferably, the line width of all sections of the fan-out lines located in the first fan-out area, except for all the first extension segments, is the second line width; preferably, the line width of the first extension segment of the first fan-out line is greater than the second line width; preferably, the minimum line width of the first extension segments of all the second progressive fan-out lines is equal to the second line width; preferably, the difference between the line widths of corresponding first extension segments of any two adjacent second progressive fan-out lines is equal; and preferably, two adjacent fan-out lines are equal in length. This embodiment is arranged such that, from the second progressive fan-out lines and the first fan-out line, the resistance difference between two adjacent fan-out lines is small, and the difference in resistance variations caused by process variations during manufacturing is also small, which can relieve the phenomenon of vertical stripes. It should be noted that the first line width segment in the second progressive fan-out line is the corresponding third extension segment.

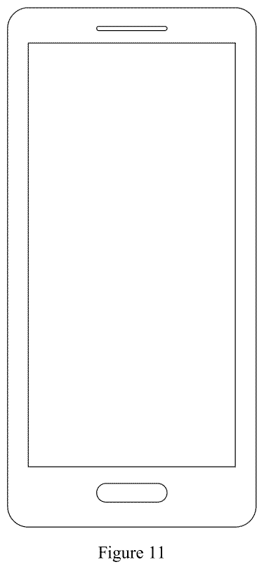

The present disclosure further provides a display device. As shown in FIG. 11, FIG. 11 is a schematic diagram of a structure of a display device according to an embodiment of the present disclosure. The display device includes a display panel according to any embodiment of the present disclosure. The display device may be a mobile phone, a tablet, an MP3, an MP4, a smart watch, a smart helmet, or other wearable devices, and so on. As the display device includes the display panel according to any embodiment of the present disclosure, it also possesses the same beneficial effects, which will not be repeated here.

It should be understood that the steps may be reordered, added, or deleted using the various forms of processes illustrated above. For example, the steps recorded in the present disclosure may be performed in parallel, sequentially, or in a different order, provided that the desired results of the embodiments of the present disclosure can be achieved, which are not limited here.

The above detailed description does not constitute a limitation on the scope of protection of the present disclosure. It should be understood in the art that various modifications, combinations, sub-combinations, and substitutions can be made based on design requirements and other factors. A ny modifications, equivalent substitutions, or improvements made within the spirit and principle of the present disclosure should be included within the scope of protection of the present disclosure.

1. A display panel, comprising an active area and a non-active area, wherein the non-active area comprises:
a first fan-out area, a bending area and a second fan-out area which are sequentially away from the active area; the active area comprises a plurality of first signal lines extending in a first direction and arranged in a second direction, the first direction intersecting the second direction;
the non-active area also comprises a plurality of fan-out lines electrically connected to the plurality of first signal lines, respectively; the bending area is provided with a plurality of avoidance areas, and the fan-out lines are separated from the avoidance areas;
two fan-out lines adjacent to the avoidance area in the second direction and on different sides of the avoidance area comprises a first fan-out line and a second fan-out line, a section of the first fan-out line in the first fan-out area comprises a first extension segment and a second extension segment connected to the first extension segment;
a section of the second fan-out line in the second fan-out area comprises a first extension segment and a second extension segment connected to the first extension segment; the first extension segments of the two fan-out lines are adjacent to the avoidance area and on opposite sides of the avoidance area in the first direction; and the first extension segments of the two adjacent fan-out lines on different sides of the avoidance area have the same line width.

2. The display panel according to claim 1, wherein the active area and the non-active area are arranged in the first direction, and in the same fan-out line, an included angle between the first extension segment and the second direction is smaller than an included angle between a corresponding second extension segment and the second direction; or
the first extension segment is collinear with the second extension segment, and in the first direction, an orthographic projection of the first extension segment overlaps a projection of a corresponding avoidance area, and an orthographic projection of the second extension segment does not overlap a projection of the corresponding avoidance area.

3. The display panel according to claim 1, wherein in the first and second fan-out lines adjacent to the avoidance area in the second direction and on different sides of the avoidance area, the section of the first fan-out line located in the first fan-out area comprises a first extension segment and a second extension segment, and the section of the second fan-out line located in the second fan-out area comprises a first extension segment and a second extension segment; wherein the first fan-out line is close to a centerline of the bending area, the second fan-out line is away from the centerline of the bending area, and the centerline extends in the first direction and is in a center of the bending area in the second direction; and
the section of the first fan-out line located in the second fan-out area comprises a third extension segment, and the section of the second fan-out line located in the first fan-out area comprises a third extension segment.

4. The display panel according to claim 3, wherein the first extension segment of the first fan-out line is collinear with a corresponding second extension segment, and an included angle between the first extension segment of the second fan-out line and the second direction is smaller than an included angle between the corresponding second extension segment and the second direction;
the third extension segment of the first fan-out line extends parallel to the second extension segment of the second fan-out line; and
a length difference between the third extension segment of the first fan-out line and the second extension segment of the second fan-out line is less than or equal to a first preset value.

5. The display panel according to claim 4, wherein the plurality of fan-out lines comprise a plurality of first progressive fan-out lines disposed on the side of the second fan-out line away from the centerline of the bending area;
each of the first progressive fan-out lines comprises a first extension segment and a second extension segment located in the second fan-out area;
in a plurality of first extension segments of the plurality of first progressive fan-out lines corresponding to the second fan-out line, the widths of different first extension segments gradually increase in a direction away from the centerline of the bending area.

6. The display panel according to claim 5, wherein the line width of all sections of the fan-out lines located in the second fan-out area, except for all the first extension segments, is a first line width;
the line width of the first extension segment of the second fan-out line is smaller than the first line width;
the maximum line width of the first extension segments of all the first progressive fan-out lines is equal to the first line width; and
the difference between the line widths of corresponding first extension segments of any two adjacent first progressive fan-out lines is equal.

7. The display panel according to claim 3, wherein an included angle between the first extension segment of the first fan-out line and the second direction is less than an included angle between a corresponding second extension segment and the second direction, the first extension segment of the second fan-out line being collinear with a corresponding second extension segment;
the second extension segment of the first fan-out line extends parallel to the third extension segment of the second fan-out line;
the length difference between the second extension segment of the first fan-out line and the third extension segment of the second fan-out line is less than or equal to a second preset value.

8. The display panel according to claim 7, wherein the plurality of fan-out lines comprise a plurality of second progressive fan-out lines disposed on the side of the first fan-out line close to the centerline of the bending area;
each of the second progressive fan-out lines comprises a first extension segment and a second extension segment located in the first fan-out area; in the first extension segments of the first fan-out line corresponding to the plurality of second progressive fan-out lines, the widths of different first extension segments gradually decrease in a direction close to the centerline of the bending area.

9. The display panel according to claim 8, wherein, the line width of all sections of the fan-out lines located in the first fan-out area, except for all the first extension segments, is the second line width;
the line width of the first extension segment of the first fan-out line is greater than the second line width;
the minimum line width of the first extension segments of all the second progressive fan-out lines is equal to the second line width; and
the difference between the line widths of corresponding first extension segments of any two adjacent second progressive fan-out lines is equal.

10. The display panel according to claim 3, wherein an included angle between the first extension segment of the first fan-out line and the second direction is less than an included angle between a corresponding second extension segment and the second direction, and an included angle between the first extension segment of the second fan-out line and the second direction is smaller than an included angle between a corresponding second extension segment and the second direction;
the second extension segment of the first fan-out line extends parallel to the third extension segment of the second fan-out line;
a length difference between the second extension segment of the first fan-out line and the third extension segment of the second fan-out line is less than or equal to a third preset value;
the third extension segment of the first fan-out line extends parallel to the second extension segment of the second fan-out line; and
the length difference between the third extension segment of the first fan-out line and the second extension segment of the second fan-out line is less than or equal to a fourth preset value.

11. The display panel according to claim 10, wherein the plurality of fan-out lines comprise a plurality of first progressive fan-out lines disposed on the side of the second fan-out line away from the centerline of the bending area; each of the first progressive fan-out lines comprises a first extension segment and a second extension segment located in the second fan-out area; in a plurality of first extension segments of the plurality of first progressive fan-out lines corresponding to the second fan-out line, the widths of different first extension segments gradually increase in a direction away from the centerline of the bending area.

12. The display panel according to claim 11, wherein, the line width of all sections of a fan-out lines located in a second fan-out area, except for all the first extension segments, is a first line width; the line width of a section of fan-out line located in the first fan-out area is a second line width;
the line width of a first extension segment of the second fan-out line is smaller than the first line width;
the maximum line width of the first extension segments of all the first progressive fan-out lines is equal to the first line width; and
the difference between the line widths of corresponding first extension segments of any two adjacent first progressive fan-out lines is equal.

13. The display panel according to claim 11, wherein a plurality of fan-out lines comprise a plurality of second progressive fan-out lines disposed on the side of a first fan-out line close to the centerline of a bending area; each of the second progressive fan-out lines comprises a first extension segment and a second extension segment located in a first fan-out area; in the first extension segments of the first fan-out line corresponding to the plurality of second progressive fan-out lines, the widths of different first extension segments gradually decrease in a direction close to the centerline of the bending area;
the line width of all sections of the fan-out lines located in the first fan-out area, except for all the first extension segments, is the second line width; the line width of a section of the fan-out line located in the second fan-out area is the first line width;
the line width of the first extension segment of the first fan-out line is greater than the second line width;
the minimum line width of the first extension segments of all the second progressive fan-out lines is equal to the second line width; and
wherein, the difference between the line widths of corresponding first extension segments of any two adjacent second progressive fan-out lines is equal.

14. The display panel according to claim 10, wherein the first extension segment of the first fan-out line extends parallel to the first extension segment of the second fan-out line.

15. The display panel according to claim 1, wherein the bending area further comprises a plurality of hub areas, the hub areas and the avoidance areas being arranged in the second direction; and
a section of the fan-out line located in the bending area is disposed in the hub area.

16. The display panel according to claim 1, further comprising a plurality of second signal lines arranged within the active area, a plurality of direct-current signal lines are arranged in the avoidance area, and the direct-current signal lines are electrically connected to the second signal lines.

17. The display panel according to claim 1, wherein the active area further comprises a plurality of pixel drive circuits arranged in an array; the first signal lines are configured to provide a data signal to the pixel drive circuits; and
the pixel drive circuits in the same line in the first direction are electrically connected to the same first signal line.

18. A display panel, comprising:
an active area and a non-active area, wherein the non-active area comprises a bending area; the active area comprises a plurality of first signal lines extending in a first direction and arranged in a second direction, the first direction intersecting the second direction;
the non-active area also comprises a plurality of fan-out lines electrically connected to the plurality of first signal lines, respectively; the bending area is provided with a plurality of avoidance areas, and the fan-out lines are separated from the avoidance areas; and
two fan-out lines, which are adjacent to the avoidance area in the second direction and on different sides of the avoidance area, are equal in length, and each of the fan-out lines comprises a first line width segment and a second line width segment.

19. The display panel according to claim 18, wherein the active area and the non-active area are arranged in the first direction, and the non-active area comprises a first fan-out area, a bending area and a second fan-out area which are sequentially away from the active area;
in the two fan-out lines adjacent to the avoidance area in the second direction and on different sides of the avoidance area, a section of one fan-out line in the first fan-out area comprises a first extension segment and a second extension segment connected to the first extension segment; a section of the other fan-out line in the second fan-out area comprises a first extension segment and a second extension segment connected to the first extension segment; and
in the same fan-out line, an included angle between the first extension segment and the second direction is smaller than an included angle between a corresponding second extension segment and the second direction; or the first extension segment is collinear with the second extension segment, and in the first direction, an orthographic projection of the first extension segment overlaps a projection of a corresponding avoidance area, and an orthographic projection of the second extension segment does not overlap a projection of the corresponding avoidance area,
wherein the second line width segment of the first fan-out line comprises a corresponding first extension segment and a corresponding second extension segment;
the first line width segment of the first fan-out line comprises a corresponding third extension segment;
the second line width segment of a second fan-out line comprises a corresponding third extension segment and a corresponding first extension segment; and the first line width segment of the second fan-out line comprises a corresponding second extension segment,
wherein the width of the first line width segment of the fan-out line is greater than the width of a corresponding second line width segment, wherein the plurality of fan-out lines comprise a plurality of first progressive fan-out lines disposed on the side of the second fan-out line away from the centerline of the bending area; each of the first progressive fan-out lines comprises a first extension segment and a second extension segment located in the second fan-out area;
in a plurality of first extension segments of the plurality of first progressive fan-out lines corresponding to the second fan-out line, the widths of different first extension segments gradually increase in a direction away from the centerline of the bending area.

20. The display panel according to claim 18, wherein the first line width segment of a first fan-out line comprises a corresponding first extension segment and a corresponding second extension segment;
the second line width segment of the first fan-out line comprises a corresponding third extension segment; the second line width segment of the second fan-out line comprises a corresponding second extension segment and a corresponding first extension segment; and
the first line width segment of the second fan-out line comprises a corresponding third extension segment,
wherein the width of the first line width segment of the fan-out line is greater than the width of a corresponding second line width segment,
wherein the plurality of fan-out lines comprise a plurality of second progressive fan-out lines disposed on the side of the first fan-out line close to the centerline of the bending area;
each of the second progressive fan-out lines comprises a first extension segment and a second extension segment located in a first fan-out area;
in the first extension segments of the first fan-out line corresponding to the plurality of second progressive fan-out lines, and the widths of different first extension segments gradually decrease in a direction close to the centerline of the bending area.
